(19) United States
(12) Patent Application Publication
(10) Pub. No.: US 2004/0150000 A1
(43) Pub. Date: Aug. 5, 2004

(54) Semiconductor device

(76) Inventors: Masaru Takaishi, Kyoto (JP); Hiroyuki Tamada, Kyoto (JP)

Correspondence Address: RABIN & BERDO, P.C., Suite 500, 1101 14th Street, N.W., Washington, DC, 20005, US

(21) Appl. No.: 10/748,276

(22) Filed: Dec. 31, 2003

(30) Foreign Application Priority Data
Jan. 14, 2003 (JP) 2003-006255

(51) Int. Cl. H01L 29/74; H01L 31/111

(52) U.S. Cl. 257/173

(57) ABSTRACT

A semiconductor device, including: a semiconductor chip having a polarity; and a plurality of protection diodes connected in series with polarities thereof being arranged in the same direction, the protection diodes and the semiconductor chip being connected in parallel with the polarities of the protection diodes being arranged in the same direction as the arrangement of polarities of the semiconductor chip.

### BACKGROUND OF THE INVENTION

1. Field of the Invention

The present invention relates to a semiconductor device that is hardly damaged by the thermal runaway.

2. Description of Related Art

In a semiconductor device including a semiconductor chip that needs a high heat-radiating capability, for example, a laser diode, the semiconductor chip is joined onto a submount having high thermal conductivity. This allows the semiconductor chip to release heat effectively, and thereby allows a semiconductor element formed on the semiconductor chip to maintain a satisfactory characteristic. Such a submount is disclosed, for example, in Japanese Laid-open Patent Application No. 179589/1986.

FIG. 6 is a schematic cross section of a semiconductor device including a conventional submount. The semiconductor device includes stems 51 and 52, which are a pair of metal strip materials, a submount 53 joined onto one surface of the stem 51, and a laser diode 54 joined onto the submount 53.

The stems 51 and 52 extend in a direction perpendicular to the sheet surface of FIG. 6 in parallel with each other. The submount 53 has a shape of a flat rectangular prism, and is joined to the stem 51 on one surface. The laser diode 54, which has a shape of a flat rectangular prism narrower than the submount 53 in width, is joined to the other surface of the submount 53 in parallel with the submount 53. A pair of electrodes is formed on the laser diode 54: one on the surface joined to the submount 53 and the other on the surface on the opposite side.

The submount 53 comprises a silicon substrate 55 having conduction of a P⁺-type and an epitaxial layer 56 having conduction of an N⁻-type formed thereon, and is directed to the stem 51 on the surface on which the epitaxial layer 56 is not formed. In the epitaxial layer 56 is formed a first diffusing layer 57 having conduction of a P-type in substantially the same size and shape as those of the laser diode 54 when viewed in a plane looking down the silicon substrate 55 perpendicularly. The first diffusing layer 57 is formed only in the vicinity of the surface of the epitaxial layer 56.

A second diffusing layer 58 having conduction of a P⁺-type is formed in the vicinity of the periphery of the submount 53. The second diffusing layer 58 is formed to penetrate through the epitaxial layer 56 in the thickness direction thereof in a region spaced apart from the first diffusing layer 57, and is connected to the silicon substrate 55. In other words, the epitaxial layer 56, whichhas the conduction type different from those of the first diffusing layer 57 and the second diffusing layer 58, is present between these two layers 57 and 58.

An insulation film 63 is formed on the surface of the epitaxial layer 56 in a pattern through which a major portion of the first diffusing layer 57 and part of the second diffusing layer 58 are exposed. A metal film 59 made of aluminum (Al) is formed in a region including the exposed portion of the first diffusing layer 57. A metal film 60 made of aluminum is formed on the exposed portion of the second diffusing layer 58. The metal films 59 and 60 come in contact with the first and second diffusing layers 57 and 58, respectively; however, both are electrically isolated from the N⁻-type portion of the epitaxial layer 56 by the insulation film 63.

The laser diode 54 is joined onto the metal film 59 so as to overlap the first diffusing layer 57 almost entirely. The metal film 59 is provided extendedly on the outside of the opposing portion of the laser diode 54 and the first diffusing layer 57, and the extended portion of the metal film 59 is connected to the stem 52 through a bonding wire 62. According to this configuration, the electrode formed on the laser diode 54 on the surface on the metal film 59 side is electrically connected to the stem 52.

The electrode formed on the laser diode 54 on the surface opposite to the metal film 59 side is connected to the metal film 60 through a bonding wire 61. Both the second diffusing layer 58 and the silicon substrate 55 have conduction of a P⁺-type, and are therefore electrically conducting. According to this configuration, the electrode formed on the laser diode 54 on the surface opposite to the metal film 59 side is electrically connected to the stem 51.

Hence, by energizing between the stem 51 and stem 52 in a certain polarity, the laser diode 54 becomes able to emit light. Heat generated in the laser diode 54 in association with the flowing electrical current is dissipated in a satisfactory manner via the submount 53 made of silicon having high thermal conductivity, which prevents an excessive rise of temperature in the laser diode 54. This allows the laser diode 54 to maintain a satisfactory light-emitting characteristic.

The silicon substrate 55, the epitaxial layer 56, and the first diffusing layer 57 have conduction of P-, N-, and P-types, respectively, and they are therefore equivalent to two diodes connected in series with the polarities being reversed with each other. Hence, the laser diode 54 and the first diffusing layer 57 are, in general, electrically separated.

In a case where a forward voltage is applied to the laser diode 54, however, a current flowing through the laser diode 54 increases gradually as the voltage becomes higher (indicated by a broken line in FIG. 5). The above-described semiconductor device is used in such amanner that the value of a current flowing through the laser diode 54 does not exceed a predetermined level. However, the laser diode 54 has a risk of being damaged by thermal runaway, that is, while a rise of temperature and an increase of the current value of the laser diode 54 due to heating occur repetitively.

### SUMMARY OF THE INVENTION

It is therefore an object of the invention to provide a semiconductor device that is hardly damaged by thermal runaway.

A semiconductor device of the invention includes: a semiconductor chip having a polarity; and a plurality of first protection diodes connected in series with polarities thereof being arranged in a same direction, the first protection diodes and the semiconductor chip being connected in parallel with the polarities of the first protection diodes being arranged in a same direction as an arrangement of polarities of the semiconductor chip.

The plurality of first protection diodes connected in series with the polarities being arranged in the same direction have a characteristic that a current drastically increases at a given voltage as an applied forward-biased voltage becomes higher. Hence, in a circuit inwhich the first protection diodes as described above and the semiconductor chip are connected in parallel with the polarities being arranged in the same direction, a current flowing through the first protection diodes drastically increases when a forward-biased applied voltage exceeds a given voltage. This prevents a current from flowing through the semiconductor chip and the semiconductor chip is thereby protected from thermal runaway.

The value of a voltage at which the value of a current drastically increases can be adjusted by the number of the first protection diodes connected in series or the area of a P-N junction surface of the first protection diode. The number of the first protection diodes connected in series may be, for example, three to six.

The semiconductor device may further include a submount, to which the semiconductor chip is joined, to dissipate heat generated in the semiconductor chip.

In this case, the first protection diodes may be provided separately from the submount or may be formed in the submount. In a case where the first protection diodes are formed in the submount, a labor of providing the first protection diodes in addition to the submount can be eliminated. Alternatively, the first protection diodes may include both those provided separately from the submount and those formed in the submount.

The submount may include: a semiconductor substrate having a first conduction type and made of one of silicon, silicon carbide, and diamond; and an epitaxial layer having the first conduction type and formed on one surface of the semiconductor substrate. In this case, each of the plurality of first protection diodes may include: a first diffusing layer having a second conduction type, which is different from the first conduction type, and formed in a vicinity of a surface of the epitaxial layer; and a second diffusing layer having the first conduction type and formed in a vicinity of a surface of the first diffusing layer in a region spaced apart from a region having the first conduction type of the epitaxial layer.

The semiconductor substrate made of any one of silicon, silicon carbide, and diamond has high thermal conductivity, and heat generated in the semiconductor chip can be therefore dissipated in a satisfactory manner via the semiconductor substrate.

Because the first diffusing layer and the second diffusing layer have different condition types, these components form a diode. Hence, by adequately choosing the conduction types of the first and second diffusing layers, it is possible to allow the diode thus formed to function as the first protection diode that prevents (shuts down) thermal runaway of the semiconductor chip.

The first diffusing layer may be provided in a plural number in the epitaxial layer while being spaced apart from one another. In this case, the second diffusing layer maybe formed in the vicinity of the surface of each of the first diffusing layers. The first diffusing layer and the second diffusing layer formed therein in each pair constitute the first protection diode. The first diffusing layer belonging to the first protection diode in a given pair, and the second diffusing layer belonging to the first protection diode in another pair may be electrically connected, for example, by a metal film formed on the surface of the epitaxial layer.

The first protection diode is not necessarily formed in the epitaxial layer of the submount, and for example, it may be formed separately from the submount.

The submount may further include a third diffusing layer having the second conduction type and forming a second protection diode together with the epitaxial layer, the third diffusing layer being formed in the vicinity of the surface of the epitaxial layer in a joined region to the semiconductor chip.

The semiconductor chip and the second protection diode may be connected in parallel with the polarities being reversed with respect to the second protection diode. In this case, the semiconductor chip can be protected from a reverse-biased voltage by the rectification of the second protection diode.

To be more specific, when a forward-biased voltage is applied to the semiconductor chip in the above-described connection, a reverse-biased voltage is applied to the second protection diode, and therefore, a current flows only through the semiconductor chip and not through the second protection diode. On the other hand, in a case where a reverse-biased voltage is applied to the semiconductor chip, a forward-biased voltage is applied to the second protection diode and a current flows only through the second protection diode, so that the semiconductor chip is protected. This eliminates the need to provide a protection diode used to protect the semiconductor chip from a reverse-biased voltage in addition to the submount.

The conduction type of the semiconductor portion of the submount can be chosen in a way that a semiconductor chip and the protection diode can be readily connected to each other in the above-described relation. For example, the first conduction type may be the P-type and the second conduction type may be the N-type. An insulation film made of silicon dioxide or the like maybe formed on the surface of the submount to prevent the semiconductor chip from coming in contact with the submount in portions other than the third diffusing layers.

The semiconductor chip may include an electrode on the second conduction type side. In this case, the submount may further include a fourth diffusing layer having the first conduction type and used for an electrical connection to the electrode, the fourth diffusing layer being formed in the vicinity of the surface of the epitaxial layer and having a higher concentration of an impurity than the epitaxial layer.

According to this configuration, satisfactory ohmic contact can be achieved between the electrode on the second conduction type side formed on the semiconductor chip and the epitaxial layer by the fourth diffusing layer having a high concentration of an impurity. The electrode on the second conduction type side on the semiconductor chip and the fourth diffusing layer can be electrically connected to each other via a wiring member, such as a bonding wire. Because all the semiconductor substrate, the epitaxial layer, and the fourth diffusing layer have the first conduction type, a current is allowed to flow across the interfaces. Hence, the semiconductor chip can be brought into electrical conduction through the semiconductor substrate (submount) via a surface opposite to a surface to which the semiconductor chip is joined.

The semiconductor chip may be a laser diode.

The laser diode generates heat considerably when it emits light. According to this configuration, however, not only can heat generated in the laser diode be released effectively via the submount, but also the laser diode is allowed to maintain a satisfactory light-emitting characteristic by preventing thermal runaway with the use of the first protection diodes.

The above and other objects, features, and advantages of the invention will become more apparent from the following description of embodiments with reference to the accompanying drawings.

### BRIEF DESCRIPTION OF THE DRAWINGS

FIG. 1 is a schematic perspective view showing a configuration of a semiconductor device according to one embodiment of the invention;

FIG. 2 is a schematic cross section of the semiconductor device shown in FIG. 1;

FIG. 3 is schematic plane view of a submount looking down a surface on which aluminum films are formed;

FIG. 4 is a diagram showing an electrical equivalent circuit of the semiconductor device shown in FIG. 1 and FIG. 2;

FIG. 5 is a view showing a current-to-voltage characteristic of the semiconductor device shown in FIG. 1 and FIG. 2 when a voltage is applied so that a forward-biased voltage is applied to a laser diode; and

FIG. 6 is a schematic cross section of a semiconductor device including a conventional submount.

### DESCRIPTION OF THE PREFERRED EMBODIMENTS

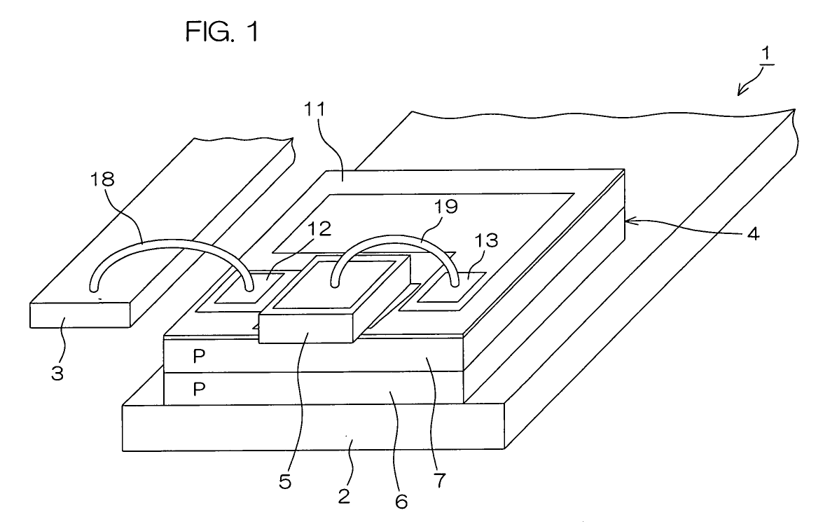

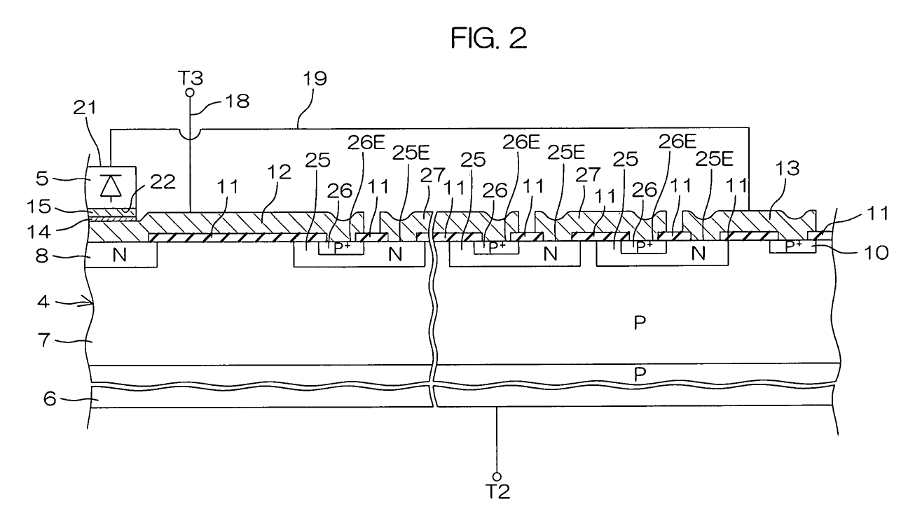

FIG. 1 is a schematic perspective view showing a configuration of a semiconductor device 1 according to one embodiment of the invention. FIG. 2 is a schematic cross section of the semiconductor device 1 shown in FIG. 1.

The semiconductor device 1 includes stems 2 and 3, which are a pair of metal strip materials (elongate plate-like members), a submount 4 joined onto one surface of the stem 2, and a laser diode 5 joined onto the submount 4.

The stem 2 and stem 3 are placed in such a manner that their length directions and thickness directions almost agree with each other. The submount 4 has a shape of an almost square when viewed in a plane, flat rectangular prism, and one surface of the submount 4 is joined to the stem 2. The length and the width of the submount 4 are slightly shorter than the width of the stem 2, and the length direction of the stem 2 and the length (width) direction of the submount 4 almost agree with each other. The submount 4 is joined to the stem 2 at the intermediate portion in the width direction thereof, and the edge face of the stem 2 is almost flush with one end face of the submount 4.

The laser diode 5 has a shape of an almost square when viewed in a plane, flat rectangular prism, and one surface of the laser diode 5 is joined to the other surface of the submount 4 (the surface opposite to the surface joined to the stem 2). The length and the width of the laser diode 5 are shorter than the length and the width of the submount 4. The length (width) direction of the laser diode 5 almost agrees with the length (width) direction of the submount 4.

The laser diode 5 is joined to the submount 4 at almost the intermediate portion in the width direction of the stem 2, and slightly protrudes from the end face of the stem 2 on the edge side. On the laser diode 5, an electrode 21 on the N-side is formed on the surface opposite to the surface joined to the submount 4, and an electrode 22 on the P-side is formed on the surface joined to the submount 4 (not shown in FIG. 1).

The submount 4 includes a silicon substrate 6 having conduction of a P-type, and an epitaxial layer 7 having conduction of a P-type is formed on one surface of the silicon substrate 6. The silicon substrate 6 is directed to the stem 2 on the surface on which the epitaxial layer 7 is not formed. The thickness of the epitaxial layer 7 is, for example, approximately 5.0 μm.

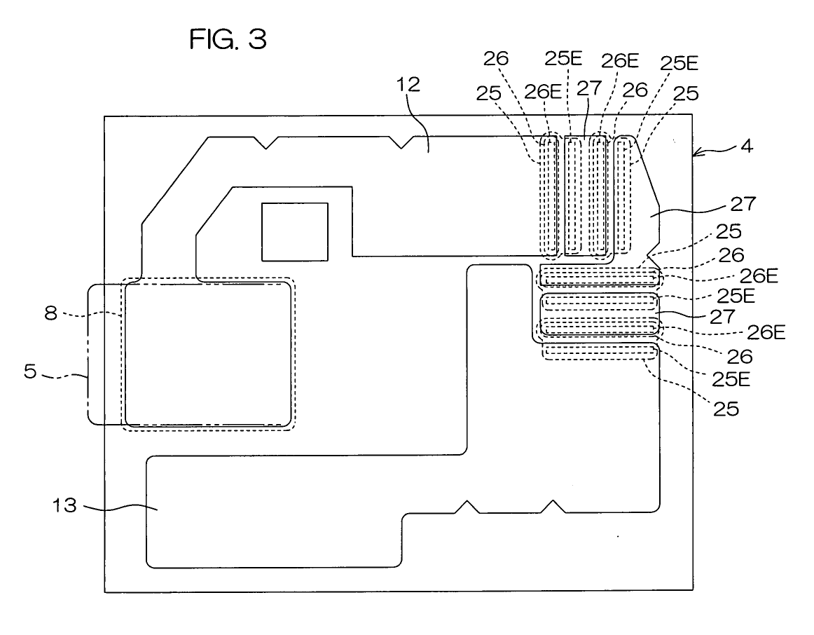

FIG. 3 is a schematic plane view of the submount 4 looking down the surface to which the laser diode 5 is joined.

Referring to FIG. 2 and FIG. 3, a plurality of first diffusing layers 25 (herein, four of them, and only three of them are shown in FIG. 2) are formed to be spaced apart from one another in the vicinity of the surface of the epitaxial layer 7 in a region avoiding a joined portion to the laser diode 5. Each first diffusing layer 25 has conduction of an N-type.

A second diffusing layer 26 having conduction of a P⁺-type is formed along a certain depth from the surface of each first diffusing layer 25. The thickness of the second diffusing layers 26 is smaller than the thickness of the first diffusing layers 25. The second diffusing layers 26 are present within the region of the corresponding first diffusing layers 25 when viewed in a plane looking down the submount 4 perpendicularly. Hence, the second diffusing layers 26 and a P-type portion of the epitaxial layer 7 do not come in direct contact as they are separated by the first diffusing layers 25.

A third diffusing layer 8 having conduction of an N⁺-type is formed in the vicinity of the surface of the epitaxial layer 7 in a region including a joined region to the laser diode 5. The third diffusing layer 8 is formed along a certain depth from the surface of the epitaxial layer 7. The thickness of the third diffusing layer 8 is smaller than the thickness of the epitaxial layer 7, and is for example, approximately 2.0 μm. When viewed in a plane looking down the submount 4 perpendicularly, the third diffusing layer 8 is substantially the same as the laser diode 5 both in size and shape.

A fourth diffusing layer 10 having conduction of a P⁺-type is formed in the vicinity of the edge portion of the submount 4. The fourth diffusing layer 10 is formed in the vicinity of the surface of the epitaxial layer 7. Also, the fourth diffusing layer 10 is formed in a region spaced apart from the first through third diffusing layers 25, 26, and 8. An insulation film 11, made of silicon dioxide (SiO₂), is formed on the surface of the epitaxial layer 7 in a pattern through which part of the first diffusing layers 25, and major portions of the second through fourth diffusing layers 26, 8, and 10 are exposed. In each of a plurality of pairs, the first and second diffusing layers 25 and 26 are exposed through the insulation film 11.

An aluminum (Al) film 12 is formed in a region including an exposed portion of the third diffusing layer 8 through the insulation film 11. The aluminum film 12 is provided extendedly on the outside of an opposing portion of the laser diode 5 (electrode 22 on the P-side) and the third diffusing layer 8, and thereby covers one of the exposed portions 26E of the second diffusing layers 26 through the insulation film 11. This electrically connects the exposed portion 26E being covered, the electrode 22 on the P-side of the laser diode 5, and the third diffusing layer 8.

For the first and second diffusing layers 25 and 26 in two adjacent pairs, an aluminum film 27 is formed to cover the exposed portion 25E of the first diffusing layer 25 through the insulation film 11 in one pair and the exposed portion 26E of the second diffusing layer 26 through the insulation film 11 in the other pair. This electrically connects the exposed portion 25E of the first diffusing layer 25 in one pair and the exposedportion 26E of the seconddiffusing layer 26 in the other pair. In other words, the aluminum film 27 functions as a wiring member that electrically connects the first diffusing layer 25 in one pair and the second diffusing layer 26 in the other pair.

An aluminum film 13 is formed to cover an exposed portion of the fourth diffusing layer 10 through the insulation film 11 and one of the exposed portions 25E of the first diffusing layers 25 through the insulation film 11. This electrically connects the exposed portion 25E being covered and the fourth diffusing layer 10. The aluminum films 12, 27, and 13 come in contact with any of the first through fourth diffusing layers 25, 26, 8 and 10; however, none of them comes in contact with the P-type portion of the epitaxial layer 7. The aluminum films 12, 27, and 13 account for almost half the area of the surface of the submount 4 on which these films 12, 27, and 13 are formed.

Between the aluminum film 12 and the laser diode 5 are present a titanium (Ti) film 14 and a gold/tin layer 15 made of alloy of gold (Au) and tin (Sn), which are interposed vertically in this order from the aluminum film 12 side.

Referring to FIG. 1 and FIG. 2, of the entire aluminum film 12, the extended portion on the outside of the opposing portion of the laser diode 5 and the third diffusing layer 8 is connected to the stem 3 through a bonding wire 18 made of gold. Onto the aluminum film 13 is connected one end of abonding wire 19 made of gold. The other end of the bonding wire 19 is connected to the electrode 21 on the N-side of the laser diode 5.

An unillustrated silicon nitride (SiN) film is formed on the exposed surface of the insulation film 11 through the aluminum films 12, 27, and 13, and in a region on the aluminum film 12 avoiding the joined portion to the laser diode 5 and the joined portion to the bonding wire 18, as well as in a region on the aluminum film 13 avoiding the joined portion to the bonding wire 19.

The configuration as described above forms a conductive pathway from the stem 2 to the stem 3 by way of the silicon substrate 6, the epitaxial layer 7, the fourth diffusing layer 10, the aluminum film 13, the bonding wire 19, the electrode 21 on the N-side, the laser diode 5, the electrode 22 on the P-side, the gold/tin layer 15, the titanium film 14, the aluminum film 12, and the bonding wire 18. Satisfactory ohmic contact is achieved between the aluminum film 13 and the epitaxial layer 7 by the fourth diffusing layer 10. Hence, by energizing between the stem 2 and the stem 3 in a certain polarity, the laser diode 5 becomes able to emit light.

Amajor portion of the submount 4 is made of silicon having high thermal conductivity, and in a major portion of the space between the silicon portion of the submount 4 and the laser diode 5 are present only the aluminum film 12, the titanium film 14, and the gold/tin layer 15, all of which are made ofinetal. Hence, heat generated in the laser diode 5 when it emits light is delivered to the submount 4 in a satisfactory manner and dissipated, which prevents an excessive rise of temperature in the laser diode 5. This allows the laser diode 5 to maintain a satisfactory light-emitting characteristic.

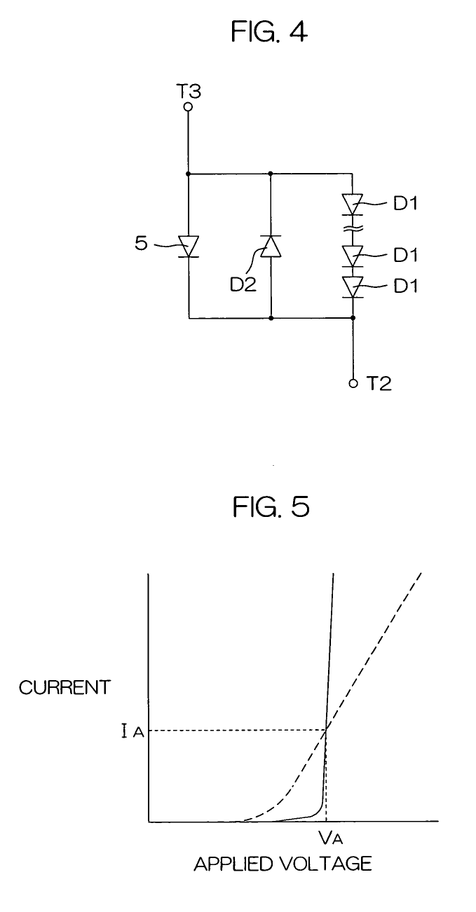

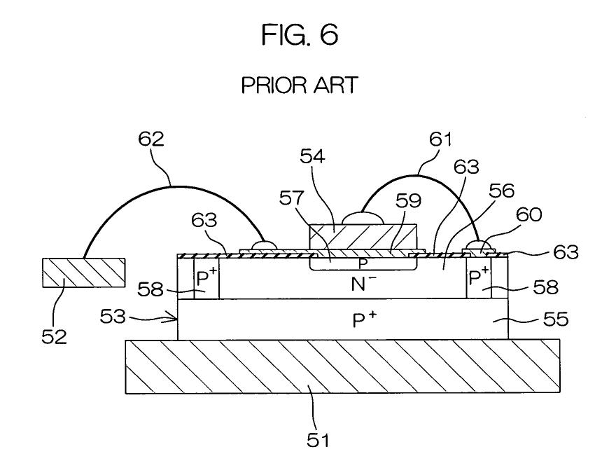

FIG. 4 is a diagram showing an electrical equivalent circuit of the semiconductor device 1 shown in FIG. 1 and FIG. 2. Besides the aforementioned conductive pathway, there is another conductive pathway from the stem 2 to the stem 3 bypassing the laser diode 5 by way of the silicon substrate 6, the epitaxial layer 7, the fourth diffusing layer 10, the aluminum film 13, four pairs of the first and second diffusing layers 25 and 26 electrically interconnected through the aluminum film 27, and the aluminum film 12 (see FIG. 1 and FIG. 2). In this conductive pathway, because the first diffusing layer 25 and the second diffusing layer 26 have different conduction types, the first and second diffusing layers 25 and 26 in each pair can be deemed as a first protection diode D1.

Further, besides the two aforementioned conductive pathways, there is still another conductive pathway from the stem 2 to the stem 3 bypassing the laser diode 5 by way of the silicon substrate 6, the epitaxial layer 7, the third diffusing layer 8, and the aluminum film 12. In this conductive pathway, because the epitaxial layer 7 and the third diffusing layer 8 have different conduction types, they can be deemed as a second protection diode D2.

Hence, as shown in FIG. 4, the semiconductor device 1 is electrically equivalent to a configuration that the laser diode 5, a serial circuit comprising a plurality of the first protection diodes D1 connected with the polarities thereof being in the same direction as those of the laser diode 5, and the second protection diode D2 with the polarities being reversed with respect to the laser diode 5 are all connected in parallel between a terminal T2 on the stem 2 side and a terminal T3 on the stem 3 side. The terminal T2 may be grounded.

FIG. 5 shows a current-to-voltage (I-V) characteristic of the semiconductor device 1 when a voltage is applied between the terminal T2 and the terminal T3 so that a forward-biased voltage is applied to the laser diode 5. In general, the semiconductor device 1 is used in such a manner that a current equal to or lower than a constant level I_{A} flows through the laser diode 5.

As indicated by a broken line in FIG. 5, the current-to-voltage characteristic of the laser diode 5 shows that the value of a current increases gradually as an applied voltage becomes higher. In a case where the first protection diodes D1 are not connected, the laser diode 5 may be damaged by thermal runaway, that is, while a rise of temperature and an increase of current of the laser diode 5 due to heating occur repetitively.

On the other hand, as indicated by a solid line in FIG. 5, the current-to-voltage characteristic of a pluralityof first protection diodes D1 shows that a current drastically increases at a certain voltage V_{A}. Hence, in a case where the first protection diodes D1 and the laser diode 5 are connected in parallel, a current mainly flows through the laser diode 5 when a voltage applied to the circuit (between the terminals T2 and T3) is equal to or lower than V_{A}. When a voltage being applied exceeds V_{A}, a current mainly flows through the first protection diodes D1. Thus, an excessive current will not flow through the laser diode 5, and the laser diode 5 can be thereby protected from damage caused by thermal runaway.

Because the first protection diodes D1 are incorporated into the submount 4, it is not necessary to provide an additional protection diode to protect the laser diode 5 from thermal runaway.

The voltage V_{A}, at which a current drastically increases, becomes higher with the number of the first protection diodes D1. Also, the voltage V_{A} becomes lower as an area of a P-N junction of the first protection diodes D1, that is, an area of the interface between the first diffusing layer 25 and the second diffusing layer 26, is increased.

Hence, the voltage V_{A} can be adjusted by the number of the first and second diffusing layers 25 and 26 and the area of the interface between the first diffusing layer 25 and the second diffusing layer 26. For example, in a case where the laser diode 5 is used, as in a usual case, at an applied voltage of 2 V, the voltage V_{A} can be set to 2.4 V with the use of four pairs of the first and second diffusing layers 25 and 26 (first protection diodes D1) each having an interface of an adequate area. In this case, the laser diode 5 can be protected from thermal runaway in a satisfactory manner.

The function of the second protection diode D2 will now be described. In order to apply a forward-biased voltage to the laser diode 5, a reverse-biased voltage is kept applied to the second protection diode D2 while the terminal T2 (stem 2) and the terminal T3 (stem 3) are energized therebetween. In this case, a current does not flow through the conductive pathway including the second protection diode D2, and a current flows only through the conductive pathway including the laser diode 5 and the conductive pathway including the first protection diodes D1.

On the other hand, a forward-biased voltage is applied to the second protection diode D2 when a voltage is applied between the terminal T2 (stem 2) and the terminal T3 (stem 3) to apply a reverse-biased voltage to the laser diode 5. Then, a current flows through the second protection diode D2, and the laser diode 5 and the first protection diodes D1 are thereby protected. Hence, the laser diode 5 can be protected from a reverse-biased voltage applied to the laser diode 5 in a satisfactory manner by the second protection diode D2.

Because the second protection diode D2 is incorporated into the submount 4, it is not necessary to provide an additional protection diode to protect the laser diode 5 from a reverse-biased voltage.

While one embodiment of the invention has been described, it should be appreciated that the invention can be implemented in another embodiment. For example, the P-type portion and the N-type portion can be inverted in the semiconductor portions of the submount 4 and the laser diode 5. The same electric property can be achieved even in this case.

The first protection diodes D1 may be provided separately from the submount 4. In this case, the first protection diodes D1 may be mounted on a wiring board to which the stems 2 and 3 are connected. The second protection diode D2 may be provided separately from the submount 4, or maybe omitted in a case where there is no risk that a reverse-biased voltage is applied to the laser diode 5.

A semiconductor chip made of silicon may be used instead of the laser diode 5. A semiconductor chip made of silicon is often attached directly onto a lead frame (stem) made of metal. However, in a case where such a structure cannot be achieved due to an attachment problem, it is possible to interpose a submount in which the same circuit as that in the submount 4 is formed between a semiconductor chip made of silicon and the lead frame by providing a semiconductor substrate made of silicon carbide (SiC) or diamond (C) instead of silicon substrate 6. As a consequence, heat generated in the semiconductor chip can be dissipated in a satisfactory manner.

While the above description described embodiments of the invention in detail, it should be appreciated that these embodiments represent examples to provide clear understanding of the technical contents of the invention, and the invention is not limited to these examples. The sprit and the scope of the invention, therefore, are limited solely by the scope of the appended claims.

This application corresponds to the Japanese Patent Application No. 2003-6255 filed with the Japanese Patent Office on Jan., 14, 2003, the entire contents of which are incorporated herein by reference.

What is claimed is:

1. A semiconductor device comprising:
a semiconductor chip having polarities; and
a plurality of first protection diodes connected in series with polarities thereof being arranged in a same direction, the first protection diodes and the semiconductor chip being connected in parallel with the polarities of the first protection diodes being arranged in a same direction as an arrangement of the polarities of the semiconductor chip.

2. A semiconductor device according to claim 1, further comprising a submount, to which the semiconductor chip is joined, to dissipate heat generated in the semiconductor chip; wherein:
the first protection diodes are formed in the submount.

3. A semiconductor device according to claim 2, wherein the submount includes:
a semiconductor substrate having a first conduction type and made of one of silicon, silicon carbide, and diamond; and
an epitaxial layer having the first conduction type and formed on one surface of the semiconductor substrate, and
wherein each of the plurality of first protection diodes includes:
a first diffusing layer having a second conduction type, which is different from the first conduction type, and formed in a vicinity of a surface of the epitaxial layer; and
a second diffusing layer having the first conduction type and formed in a vicinity of a surface of the first diffusing layer in a region spaced apart from a region having the first conduction type of the epitaxial layer.

4. A semiconductor device according to claim 3, wherein:
the first diffusing layer is provided in a plural number in the epitaxial layer while being spaced apart from one another; and
the second diffusing layer is formed in the vicinity of the surface of each of the first diffusing layers.

5. A semiconductor device according to claim 3, wherein:
the submount further includes a third diffusing layer having the second conduction type and forming a second protection diode together with the epitaxial layer, the third diffusing layer being formed in the vicinity of the surface of the epitaxial layer in a joined region to the semiconductor chip.

6. A semiconductor device according to claim 1, wherein the submount includes:
a semiconductor substrate having a first conduction type and made of one of silicon, silicon carbide, and diamond;
an epitaxial layer having the first conduction type and formed on one surface of the semiconductor substrate; and
a third diffusing layer having a second conduction type, which is different from the first conduction type, and forming a second protection diode together with the epitaxial layer, the third diffusing layer being formed in a vicinity of a surface of the epitaxial layer in a joined region to the semiconductor chip.

7. A semiconductor device according to claim 3, wherein:
the semiconductor chip includes an electrode on the second conduction type side; and
the submount further includes a fourth diffusing layer having the first conduction type and used for an electrical connection to the electrode, the fourth diffusing layer being formed in the vicinity of the surface of the epitaxial layer and having a higher concentration of an impurity than the epitaxial layer.

8. A semiconductor device according to claim 1, wherein the semiconductor chip is a laser diode.
